(19) United States
(12) Patent Application Publication
(10) Pub. No.: US 2008/0099861 A1
(43) Pub. Date: May 1, 2008

(54) Sensor device package having thermally compliant die pad

(75) Inventor: John Dangtran, San Jose, CA (US)

Correspondence Address: THELEN REID BROWN RAYSMAN & STEINER LLP, P. O. BOX 640640, SAN JOSE, CA, 95164-0640, US

(73) Assignee: S3C, Inc., a California Corporation

(21) Appl. No.: 11/975,618

(22) Filed: Oct. 19, 2007

Related U.S. Application Data
(60) Provisional application No. 60/853,500, filed on Oct. 19, 2006.

(51) Int. Cl. H01L 29/84; H01L 21/00

(52) U.S. Cl. 257/415; 438/51; 257/E29.324; 257/E21.499

(57) ABSTRACT

A sensor device and a method of forming thereof comprises a die pad having an inner portion and an outer portion. The outer portion is made of steel, aluminum or other metal and is adapted to mount the die pad to a support structure having a first coefficient of thermal expansion (CTE) value and provide a hermetic seal therewith. The outer portion is made of a material having a CTE value substantially complaint with the first CTE value. The inner portion may be made of Invar, Kovar or ceramic material to receive a MEMS device having a second CTE value. The inner portion is made of a material having a CTE value substantially compliant with the second CTE value. The outer portion has a thickness less than that of the inner portion. The die pad may include a trench between outer edges of the outer and inner portions.

### RELATED APPLICATION

The present application claims the benefit of priority based on U.S. Provisional Patent Application Ser. No. 60/853,500, filed on Oct. 19, 2006, in the name of inventor John Dangtran, entitled “SENSOR DEVICE PACKAGE HAVING THERMALL COMPLIANT DIE PAD”, all commonly owned herewith

### TECHNICAL FIELD

The present disclosure relates generally to sensor systems.

### BACKGROUND

The use of MEMS (micro-electro-mechanical systems) sensors is becoming widespread in applications where a small sensor is needed and low cost is important. In applications where the sensor is exposed to harsh environments, such as that in refrigeration and AC systems, a backside entry sensor device is used, because the top side of the sensor, which usually contains the piezo-resistive elements, cannot be exposed to the harsh conditions in the environment.

A MEMS sensor is usually used in the sensor device and attached to a support structure which is then welded or crimped to a pressure port. Support structures have a high thermal expansion mismatch between the support material and the MEMS sensor. This mismatch may cause strain, unrelated to pressure, which results in errors that are unintended into sensor measurements.

One method to reduce the strain between the MEMS sensor and the support structure is to use a thermally compliant die attach made of a silicone elastomer. However silicone elastomers may not provide a hermetic seal, thereby allowing gas or liquid to leak into the section of the sensor device having the electronic components therein when high temperatures or pressures are present in the environment surrounding the sensor device. This may cause the sensor device to leak, thereby adversely affecting the sensor readings and yielding inconsistent and inaccurate measurements. In addition, refrigeration systems and sensor systems therein are not allowed any gas or liquid leaks for environmental safety reasons as regulated by the Environmental Protection Agency (EPA).

### OVERVIEW

In an embodiment, a sensor device comprises a die pad having an inner portion and an outer portion, the outer portion adapted to mount the die pad to a support structure having a first coefficient of thermal expansion (CTE) value and provide a hermetic seal therewith, wherein the outer portion is made of a material having a CTE value substantially complaint with the first CTE value, the inner portion adapted to receive thereon a MEMS device having a second CTE value, wherein the inner portion is made of a material having a CTE value substantially compliant with the second CTE value. The inner portion may be made of either Invar, Kovar or ceramic material in an embodiment. In an embodiment, the outer portion and the support structure are made of steel. In an embodiment, the outer portion and the support structure are made of aluminum. In an embodiment, the inner portion and outer portions are disk shaped and bonded to one another, wherein the outer portion is concentric with the inner portion. In an embodiment, the outer portion has a first thickness and the inner portion has a second thickness, wherein the second thickness is greater than the first thickness. In an embodiment, the die pad includes at least one trench configured between an outer edge of the outer portion and an outer edge of the inner portion, wherein a thickness of the trench is less than a thickness of the inner portion. The inner portion includes a Nickel-Gold layer thereon to receive the MEMS device in an embodiment.

In an embodiment, a sensor device comprises a support structure at least partially made of a material having a first coefficient of thermal expansion (CTE); a die pad having an inner portion and an outer portion, the outer portion affixed to the support structure, wherein the outer portion is made of a material having a CTE substantially compliant to the first CTE; and a MEMS device coupled to the inner portion, the sensor made of a material having a second CTE, wherein the inner portion is made of a material having a CTE substantially compliant to the second CTE. The inner portion may be made of either Invar, Kovar or ceramic material in an embodiment. In an embodiment, the outer portion and the support structure are made of steel. In an embodiment, the outer portion and the support structure are made of aluminum. In an embodiment, the inner portion and outer portions are disk shaped and bonded to one another, wherein the outer portion is concentric with the inner portion. In an embodiment, the outer portion has a first thickness and the inner portion has a second thickness, wherein the second thickness is greater than the first thickness. In an embodiment, the die pad includes at least one trench configured between an outer edge of the outer portion and an outer edge of the inner portion, wherein a thickness of the trench is less than a thickness of the inner portion. The inner portion includes a Nickel-Gold layer thereon to receive the MEMS device in an embodiment.

In an embodiment, a method for forming a sensor device comprising: forming a die pad having an inner portion and an outer portion, the outer portion being made of a material having a first coefficient of thermal expansion (CTE) value, the inner portion made of a material having a second CTE value; coupling the outer portion of the die pad to a support structure to provide a hermetic seal therewith, wherein the support structure is made of a material having a CTE value substantially compliant with the first CTE value; and coupling a MEMS device to the inner portion, wherein the MEMS device is made of a material having a CTE value substantially compliant with the second CTE value. The inner portion may be made of either Invar, Kovar or ceramic material in an embodiment. In an embodiment, the outer portion and the support structure are made of steel. In an embodiment, the outer portion and the support structure are made of aluminum. In an embodiment, the inner portion and outer portions are disk shaped and bonded to one another, wherein the outer portion is concentric with the inner portion. In an embodiment, the method further comprises forming the outer portion to have a first thickness; and forming the inner portion to have a second thickness, wherein the second thickness is greater than the first thickness. In an embodiment, the method comprises forming at least one trench between an outer edge of the outer portion and an outer edge of the inner portion, wherein a thickness of the trench is less than a thickness of the inner portion. In an embodiment, the method comprises applying a Nickel-Gold layer to the inner portion.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the Drawings

FIG. 1 illustrates an exploded view of the sensor system in accordance with an embodiment.

FIG. 2 illustrates a cross sectional schematic of a support structure in accordance with an embodiment.

FIG. 3A illustrates a perspective view of a die pad in accordance with an embodiment.

FIG. 3B illustrates a perspective view of a die pad in accordance with an embodiment.

FIG. 4A illustrates an exploded view of a support structure and die pad in accordance with an embodiment.

FIG. 4B illustrates a perspective view of the support structure and die pad in accordance with an embodiment.

FIG. 5 illustrates a flow chart of the production and assembly process of the sensor system in accordance with an embodiment.

### DESCRIPTION OF EXAMPLE EMBODIMENTS

Example embodiments are described herein in the context of a sensor system. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In accordance with this disclosure, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Eraseable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card, paper tape and the like) and other types of program memory.

In general, the sensor system described herein utilizes a die pad which combines a low coefficient of thermal expansion metal with a relatively high coefficient of thermal expansion metal to provide a very low cost die pad and support structure for a silicon MEMS (Micro-electro-mechanical system) sensor system which is hermetically sealed. The subject matter described herein allows the inexpensive manufacture of an effective sensor system which may be used for absolute sensors, gage type sensors, AC and refrigeration systems sensors, braking sensors and/or other engine control sensors in vehicles, industrial and/or medical equipment.

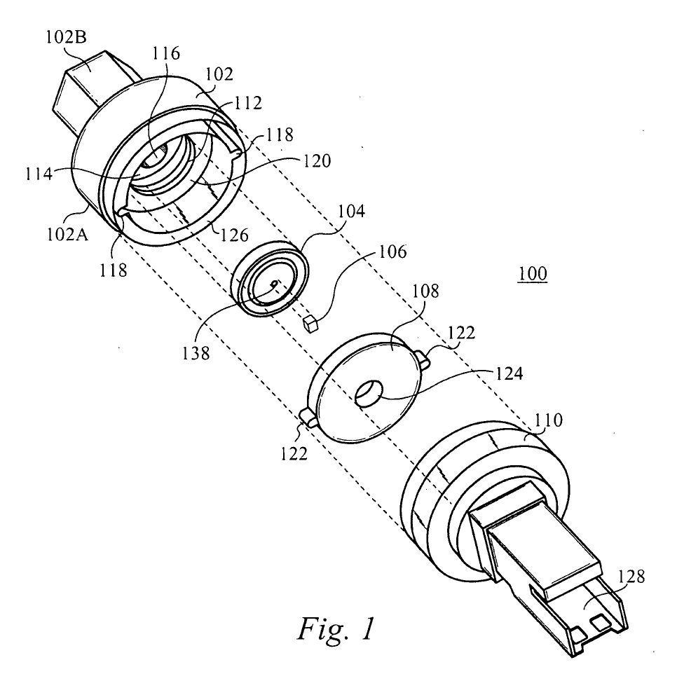

FIG. 1 illustrates an exploded view of the sensor system in accordance with an embodiment. As shown in FIG. 1, the sensor system 100 includes a support structure 102, a die pad 104, a sensor device 106, a printed circuit board 108, and a connection cap 110. It should be noted that additional and/or alternative components may be utilized in the sensor system 100 without departing from the scope of the claimed embodiments herein.

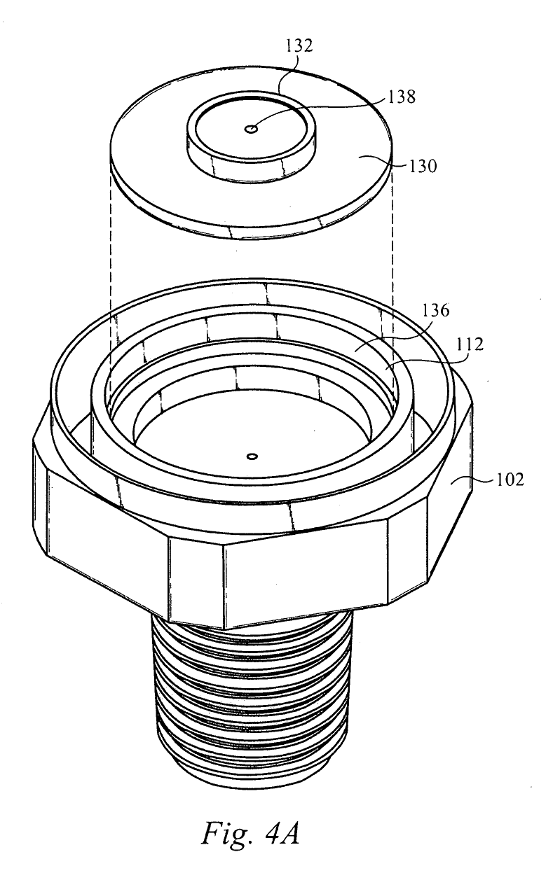

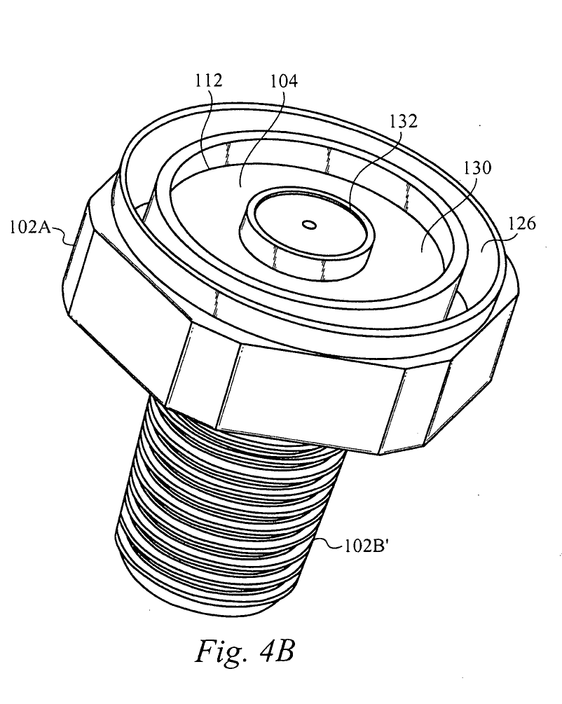

The support structure 102 includes an upper portion 102A and a lower portion 102B, whereby the lower portion 102B connects, via a pressure port, the sensor system to a relatively highly pressurized environment which is being measured by the system 100. The lower portion 102B is shown as a bolt member in FIG. 1, but may have any other appropriate design based on the port configuration of the item to which the support structure 102 is coupled. For example, the bottom portion 102B of the support structure may have a threaded configuration as shown in FIGS. 4A and 4B.

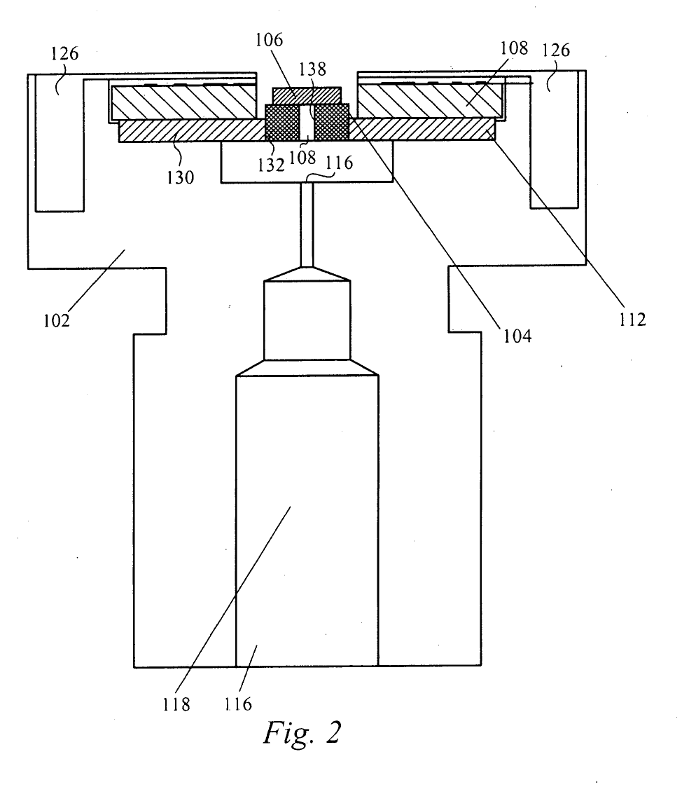

The upper portion 102A of the support structure is made of steel in an embodiment, although other appropriate metals, such as aluminum are contemplated. The upper portion 102A of the support structure 102 includes a first receiving recess 112 which receives the die pad 104 and sensor 106. In particular, the first receiving recess includes a seated area 114 upon which die pad 104 is mounted to provide a hermetic seal therebelow. The seated area 114 includes an aperture 116 in communication with a port channel 118 (FIG. 2) which extends all the way through to the bottom of the lower portion 102B of the support structure 102 in an embodiment.

As shown in FIG. 1, the support structure 102 also receives a printed circuit board (PCB) 108 in a second recess having a PCB seating area 120 in the upper portion 102A in an embodiment. In an embodiment, the PCB 108 is coupled to the seating area 120 by an adhesive, although any other appropriate coupling method is contemplated. In an embodiment, the PCB 108 includes guide extensions 122 which fit within corresponding notches 118 in the support structure 102 when the PCB 108 is received in the PCB seating area 120. In an embodiment, the guide extensions 122 are keyed, such that the PCB 108 will only properly fit within the PCB seating area 120 when properly oriented. In an embodiment, the PCB has a donut configuration which includes an aperture 124 which extends therethrough, whereby the aperture 124 is configured to be aligned with the sensor 106 and surround the sensor 106 when the PCB 108 is mounted to the support structure. In an embodiment, the sensor 106 is wire bonded to the PCB 108, although any other appropriate electrical coupling method is contemplated. The aperture 124 of the PCB 108 also allows electrical connections to be easily made between the sensor 106, the PCB 124 and the connection cap 110.

The connection cap 110 fits into the outer recess 126 in the upper portion 102B and fits over the components and electronics within the upper portion 102B of the support structure 102. The connection cap 110 may be mounted to the support structure by any appropriate methods. The connection cap 110 includes an electrical connection port 128 which allows power, signals and/or data to flow between the sensor system 100 and any other electrical components. FIG. 2 illustrates a cutaway view of the support structure 102, die pad 104, sensor 106, and PCB 108 in accordance with an embodiment.

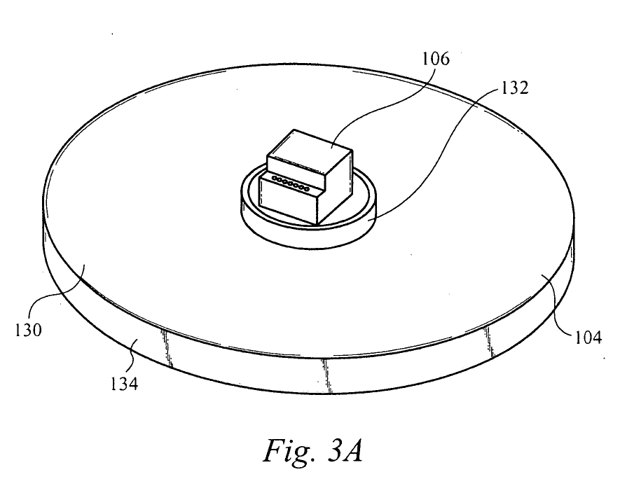

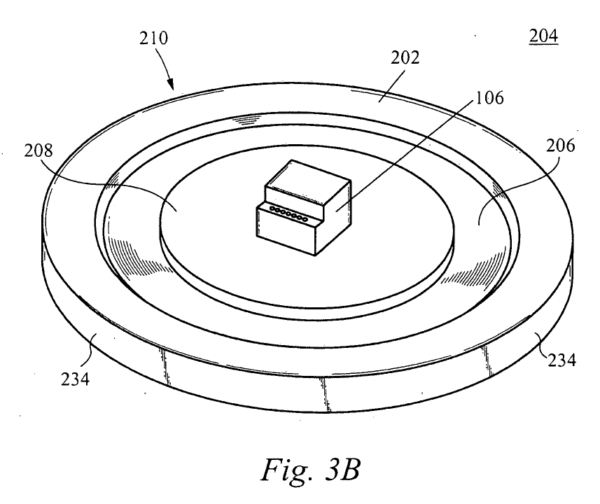

FIG. 3A illustrates a perspective view of the die pad 104 in accordance with an embodiment. The die pad 104 is configured to receive the sensor 106 thereon and is also configured to be mounted to the metal support structure 102 described above. In particular, the die pad 104 includes an inner portion 132 and an outer portion 134, whereby the inner and outer portions are made of different materials. The die pad 104 is shown to have a circular configuration. However, it is contemplated that the die pad 104 may have any other shape without digressing from the inventive concepts described herein.

The sensor 106 is attached to a top surface of the inner portion 132 as shown in FIG. 3A, whereby the sensor 106 is placed on top of the aperture 138. The sensor 106 is a MEMS sensor in an embodiment in which the MEMS sensor is, but is not limited to, pressure sensors, temperature sensors, Hall effect sensors, electromagnetic sensor and sensor arrays, humidity sensors, optical sensors, gyroscopes, accelerometers, piezoelectrics sensors or transducers, and displays. It should be noted that although only one sensor 106 is shown mounted to the center of the inner portion 132, more than one sensor is contemplated without digressing from the inventive concepts described herein. It should also be noted that multiple sensors 106 and multiple apertures 138 may be positioned at different areas on the inner portion 132.

In an embodiment, the outer edge 134 is attached to an inner wall 136 of the recess 112 in the support structure 102 as shown in FIG. 4. The die pad 104 separates and seals the highly pressurized portion of the support structure 102 below the die pad 104 from the portion of the support structure 102 above the die pad 104. As shown in FIG. 4, the die pad 104 includes the aperture 138 which extends between the top and bottom of the die pad 104. The aperture 138 is in communication with the seating area 114 as well as the port 116 of the support structure 102. As shown in FIG. 2, a sensing port of the sensor 106 is in communication with the aperture 138 when the sensor 106 is mounted to the top surface of the inner portion 132 to allow the sensor 106 to take measurements of the conditions at the port 116. In an embodiment, the inner portion 132 is raised a desired height above the outer portion 130. Considering the mismatch of CTE values between the inner and outer portions 130, 132 of the die pad 104, the rate and amount of expansion or contraction between the inner and outer portions 130, 132 may be substantially different. Due to these differences, stresses may develop at the interface between the inner and outer portions 130, 132. To isolate the stresses from being applied directly to the sensor 106, the inner portion 132 is raised a certain height above the outer portion 130. In an embodiment, the height dimension is approximately the thickness of the sensor die, although the height dimension may vary according to the materials used as well as environmental factors outside of the device 100.

The sensor 106 is configured to be in complete communication with the aperture 138, thereby effectively sealing the portion of the sensor system 100 below the die pad 104 from the portion above the die pad 104. This allows the sensor 106 to accurately read the environmental conditions below the die pad 104 without allowing gas or liquid to leak or otherwise enter into the portion of the sensor device 100 above the die pad 104.

Considering that the die pad 104 along with the sensor 106 effectively seal the upper portion 102A from the bottom portion 102B, the die pad must be securely attached to the support structure 102. The outer portion 130 is therefore securely mounted to the support structure 102 by a laser welding processor, brazing process, or other appropriate method.

The embodiment shown in FIG. 3A has an outer portion 130 which has a substantially constant thickness from the outer edge 134 to the inner portion 132. In an embodiment shown in FIG. 3B, the outer portion 210 of the die pad has different thicknesses than the inner portion 208 to form one or more isolation trenches 206 therebetween. In particular, an outer ridge 202 has a greater thickness than the trench 206, whereby the inner ridge 208 has a greater thickness than the trench 206 in an embodiment.

One cause of stress in the structure is the mismatch in CTEs between the dissimilar materials of the inner and outer portions 202, 208. This mismatch can cause significant stresses which cause swelling and/or distortion of the die pad within the support structure, thereby causing the sensor 106 to yield and break or otherwise output inaccurate results. The different thicknesses of the outer portion 210 can relieve stresses applied to the die pad 204 by the support structure in response to changes in the environmental conditions. In applying the trench isolation technique on the die pad 204, the trench 206 is to be sufficiently thick to isolate the stresses induced on the dissimilar materials of the outer and inner portions 202, 204. In an embodiment, the trench 206 is located immediately adjacent to the inner portion 208 to isolate the stresses applied to the outer edge of the inner portion 204.

In an embodiment, the recessed area 112 of the support structure 102 along with its inner surface 136 is made of steel or other appropriate material. In an embodiment, the recessed area 112 along with its inner surface 136 is made of aluminum or other similar metal. To ensure a secure attachment between the outer portion 130 of the die pad 104 and the recessed area 112 of the support structure 102, the outer portion is made of a material substantially similar or compatible to the material of the support structure 102. In an example embodiment, both the upper portion 102A of the support structure 102 and the outer portion 130 of the die pad 104 are made of stainless steel. In an example embodiment, both the upper portion 102A of the support structure 102 and the outer portion 130 of the die pad 104 are made of aluminum.

The die pad 104 serves as a strain buffer between the sensor 104 and the support structure 102 to maintain the hermetic seal in the sensor device 100. The sensor 102 is made of a silicon based material, whereas the support structure 102 is made of a material having a coefficient of thermal expansion (CTE) which is substantially different than that of the sensor 102. Considering that the outer portion 130 of the die pad 104 is rigidly attached to the support structure 102, the outer portion 130 is made of a material having a CTE compatible to the CTE of the support structure material. In addition, considering that the sensor 102 sits upon the inner portion 132 of the die pad 104, the inner portion is made of a material which has a CTE which is compatible with the CTE of the sensor 106. Thus, the outer portion 130 will expand and contract at the same rate as that of the support structure 102 material. In addition, the CTE match between the inner portion 132 of the die pad 104 and the sensor 106 maintains the seal between die pad 104 and the highly pressurized area in the support structure 102 below the die pad 104. Further, the high quality bond between the outer and inner portions 130, 132 of the die pad 104 itself maintains the overall rigidity of the die pad 104 and prevents the die pad 104 itself from failing under the high temperature and pressure conditions in the pressurized portion of the support structure. Therefore, this configuration allows the sensor 104 to be exposed to the harsh conditions of the outside environment without damaging the sensor 104 or causing the sensor 104 to make inaccurate measurements.

Such material of the inner portion 132 includes, but is not limited to, Kovar or Invar or an appropriate ceramic material without digressing from the inventive concepts herein. It is contemplated that other materials may be used for the inner portion 132 provided that the material has a coefficient of thermal expansion compatible with that of the sensor 104 and is able to be bonded with the material comprising the outer portion 130 of the die pad 104.

In an embodiment, the inner portion 132 is plated with Gold or a Nickel-Gold alloy. In an embodiment, the sensor 106 is mounted on the top surface of the inner portion 132 using a Eutectic or other hard solder. In an embodiment, the bottom side of the sensor 106 is metallized with gold for the hard solder attach with Gold/Tin (Au—Sn) or Gold-Germanium (Au—Ge) solders. In an embodiment, it may be desired to etch or machine a footprint of the bottom of the sensor 106 onto the top surface of the inner portion 132 to provide guidance in positioning the sensor 106 onto the inner portion 132 during assembly.

In an embodiment, the inner portion 132 is bonded to the outer portion 130 by using an explosion bonding technique in which the dissimilar metals are bonded to make a high-quality metal transition therebetween. The integrated bonding between the two different materials allows the sensor 106 to correctly operate and contract/expand along with the inner portion 132 while the outer portion 130 contract/expands along with the support structure 102 and maintains the overall rigidity of the die pad 104. In an embodiment, the explosion bonding technique applied between the materials in the inner and outer portions can introduce thin, diffusion inhibiting interlayers such as tantalum and titanium, whereby the interlayers can allow conventional weld-up installation. Another advantage of utilizing the explosion bonding technique between the inner and outer portions allows the dissimilar metals to be joined without losing their pre-bonded properties.

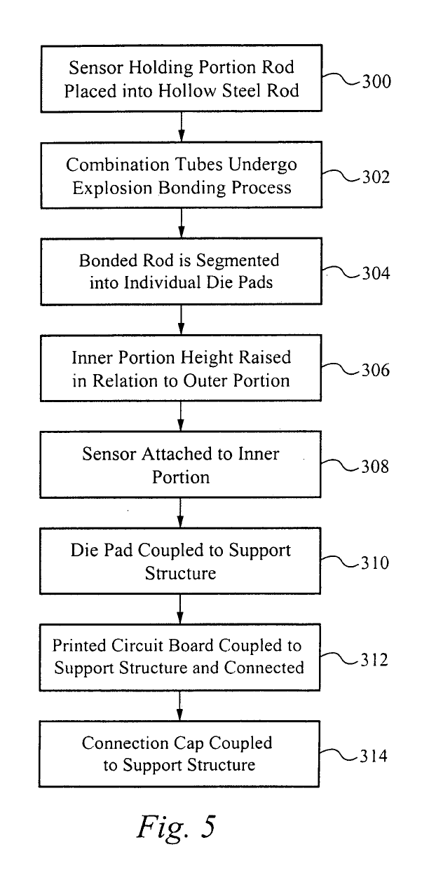

FIG. 5 illustrates a flow chart of the production and assembly process of the sensor assembly in accordance with an embodiment. In an embodiment, a tube of Invar, Kovar or other material having a CTE compliant with the sensor 106 and the inner portion 132 is inserted into a hollow tube of steel, aluminum or other material to serve as the outer portion 130 (300). Both tubes then undergo an explosion bonding process to produce a high quality bond between the inner and outer portions (302) in an embodiment. Thereafter, in an embodiment, the integrated rod is singulated into a plurality of circular die pads as those shown in the figures (304), This may be done by machining, water jetting, laser cutting or any other appropriate process.

Once the individual discs are produced, the inner portion 132 is raised a desired height above the outer portion 130 in an embodiment (306). This can be done by machining the inner and/or outer portion to the desired height or by performing any other appropriate method. In an embodiment, the inner portion 132 is plated with Nickel-Gold. The sensor 106 is then attached to the inner portion with an Eutectic solder in an embodiment (308). In an embodiment, a footprint of the bottom of the sensor 106 is etched or machined into the top surface of the inner portion 132 to provide guidance in positioning the sensor 106 onto the inner portion 132.

The die pad 104 itself is then placed in the recessed area of the structured support 102 and then attached to the structured support 102. If desired, the die pad 104 as well as the seating area may both be keyed to allow proper orientation of the die pad 104 within the support structure 102 during assembly. In an embodiment, the die pad 104 is laser welded to the structured support 102 although any other appropriate attaching method is contemplated (310).

Thereafter, the PCB 108 is attached to the structured support 102 using adhesive in an embodiment (312). The sensor is then electrically connected to the PCB 108, whereby the PCB 8 is electrically connected to the connection cap 110 which is crimped to the support structure to form the entire sensor assembly (314). It should be noted that the above method is an embodiment and the order of operations can be changed. It should also be noted that additional and/or alternative operations may be performed in assembling the sensor system 100 in embodiments.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A sensor device comprising: a die pad having an inner portion and an outer portion, the outer portion adapted to mount the die pad to a support structure having a first coefficient of thermal expansion (CTE) value and provide a hermetic seal therewith, wherein the outer portion is made of a material having a CTE value substantially complaint with the first CTE value, the inner portion adapted to receive thereon a MEMS device having a second CTE value, wherein the inner portion is made of a material having a CTE value substantially compliant with the second CTE value.

2. The sensor device of claim 1, wherein the inner portion is made of either Invar or Kovar.

3. The sensor device of claim 1, wherein the outer portion and the support structure are made of steel.

4. The sensor device of claim 1, wherein the outer portion and the support structure are made of aluminum.

5. The sensor device of claim 1, wherein the inner portion and outer portions are disk shaped and bonded to one another, wherein the outer portion is concentric with the inner portion.

6. The sensor device of claim 1, wherein the outer portion has a first thickness and the inner portion has a second thickness, wherein the second thickness is greater than the first thickness.

7. The sensor device of claim 1, wherein the die pad includes at least one trench configured between an outer edge of the outer portion and an outer edge of the inner portion, wherein a thickness of the trench is less than a thickness of the inner portion.

8. The sensor device of claim 1, wherein the inner portion includes a Nickel-Gold layer thereon to receive the MEMS device.

9. A sensor device comprising:
a support structure at least partially made of a material having a first coefficient of thermal expansion (CTE);
a die pad having an inner portion and an outer portion, the outer portion affixed to the support structure, wherein the outer portion is made of a material having a CTE substantially compliant to the first CTE; and
a MEMS device coupled to the inner portion, the sensor made of a material having a second CTE, wherein the inner portion is made of a material having a CTE substantially compliant to the second CTE.

10. The sensor device of claim 9, wherein the inner portion is made of either Invar or Kovar.

11. The sensor device of claim 9, wherein the outer portion and the support structure are made of steel.

12. The sensor device of claim 9, wherein the outer portion and the support structure are made of aluminum.

13. The sensor device of claim 9, wherein the inner portion and outer portions are disk shaped and bonded to one another, wherein the outer portion is concentric with the inner portion.

14. The sensor device of claim 9, wherein the outer portion has a first thickness and the inner portion has a second thickness, wherein the second thickness is greater than the first thickness.

15. The sensor device of claim 9, wherein the die pad includes at least one trench configured between an outer edge of the outer portion and an outer edge of the inner portion, wherein a thickness of the trench is less than a thickness of the inner portion.

16. The sensor device of claim 9, wherein the inner portion includes a Nickel-Gold layer thereon to receive the MEMS device.

17. A method for forming a sensor device comprising:
forming a die pad having an inner portion and an outer portion, the outer portion being made of a material having a first coefficient of thermal expansion (CTE) value, the inner portion made of a material having a second CTE value;
coupling the outer portion of the die pad to a support structure to provide a hermetic seal therewith, wherein the support structure is made of a material having a CTE value substantially compliant with the first CTE value; and
coupling a MEMS device to the inner portion, wherein the MEMS device is made of a material having a CTE value substantially compliant with the second CTE value.

18. The method of claim 17, wherein the inner portion is made of either Invar or Kovar.

19. The method of claim 17, wherein the outer portion and the support structure are made of steel.

20. The method of claim 17, wherein the outer portion and the support structure are made of aluminum.

21. The method of claim 17, wherein the inner portion and outer portions are disk shaped and bonded to one another using an explosion bonding technique.

22. The method of claim 17, further comprising:
forming the outer portion to have a first thickness; and
forming the inner portion to have a second thickness, wherein the second thickness is greater than the first thickness.

23. The method of claim 17, further comprising forming at least one trench between an outer edge of the outer portion and an outer edge of the inner portion, wherein a thickness of the trench is less than a thickness of the inner portion.

24. The method of claim 17, further comprising applying a Nickel-Gold layer to the inner portion.
